(19) United States
(12) Patent Application Publication
(10) Pub. No.: US 2013/0284681 A1
(43) Pub. Date: Oct. 31, 2013

(54) Waterproof structural assembly for electronic part

(71) Applicant: Kuo Sung Tsai, New Taipei (TW)

(72) Inventor: Kuo Sung Tsai, New Taipei (TW)

(21) Appl. No.: 13/457,516

(22) Filed: Apr. 27, 2012

(51) Int. Cl. H05K 7/18

(52) U.S. Cl. 211/26

(57) ABSTRACT

A structural assembly is provided with a rectangular, hollow flame including a loop flange along edges, a recess on one side of the flange, a channel through the recess, a wall facing and spaced from one end of the channel within the frame, and a groove through the wall; and a flexible sealing cap complimentary to the recess and including an outer handle, an inner engaging member spaced from the handle, an L-shaped peg on one surface of the engaging member distal the handle, and an enlargement at one end of the peg. The enlargement is larger than the peg. Width of the groove is greater than the peg. The enlargement is larger than the width of the groove. The peg and the enlargement can pass the channel. A periphery of the engaging member is greater than that of a bottom of the recess.

### BACKGROUND OF THE INVENTION

1. Field of the Invention

The invention relates to structural assemblies and more particularly to a waterproof structural assembly, together with complementary base and cover, capable of containing an electronic part (e.g., printed circuit board (PCB)).

2. Description of Related Art

The need for completely waterproof containers for handheld electronic devices (e.g., tablet computers) increases due to its wide spread use. In the past, the electronic devices have been used with various degrees of dust proofing and splash proofing. The earlier designs were primarily for protection against corrosion of the electrical terminals which could cause failure in a somewhat long term. However, this is not sufficient.

Moreover, since the engagement interface between two joined components is generally a plane, the water is able to permeate the inside of the electronic device through interstices between the joined components.

Therefore, it is desirable and necessary to design a completely waterproof structural assembly for an electronic part for preventing water from flowing into the electronic part.

### SUMMARY OF THE INVENTION

It is therefore one object of the invention to provide a structural assembly comprising a rectangular, hollow flame comprising a loop flange disposed along edges, a recess on one side of the flange, a channel through the recess to communicate with inside of the frame, a wall facing and spaced from one end of the channel within the frame, and a groove through the wall; and a flexible sealing cap complimentary to the recess, the sealing cap comprising an outer handle, an inner engaging member spaced from the handle, an L-shaped peg formed on one surface of the engaging member distal the handle, and an enlargement at one end of the peg; wherein the enlargement is larger than the peg; wherein width of the groove is greater than the peg; and wherein the enlargement is larger than the width of the groove.

The above and other objects, features and advantages of the invention will become apparent from the following detailed description taken with the accompanying drawings.

### BRIEF DESCRIPTION OF THE DRAWINGS

FIG. 1 is a perspective view of a frame of a waterproof structural assembly according to the invention;

FIG. 2 is another perspective view of the frame viewing from a different angle;

FIG. 3 is a perspective view of the sealing cap;

FIG. 4 is a perspective view of the sealing cap viewing from a different angle;

FIG. 5 is a perspective view showing the sealing cap to be joined to the recess on the frame;

FIG. 6 is a perspective view of the assembled sealing cap and frame;

FIG. 7 is a perspective view showing a PCB to be placed in the frame;

FIG. 8 is a perspective view of the assembled PCB and frame with the sealing cap being detached from the recess; and

FIG. 9 is a view similar to FIG. 8 showing details of the sealing cap being detached from the recess.

### DETAILED DESCRIPTION OF THE INVENTION

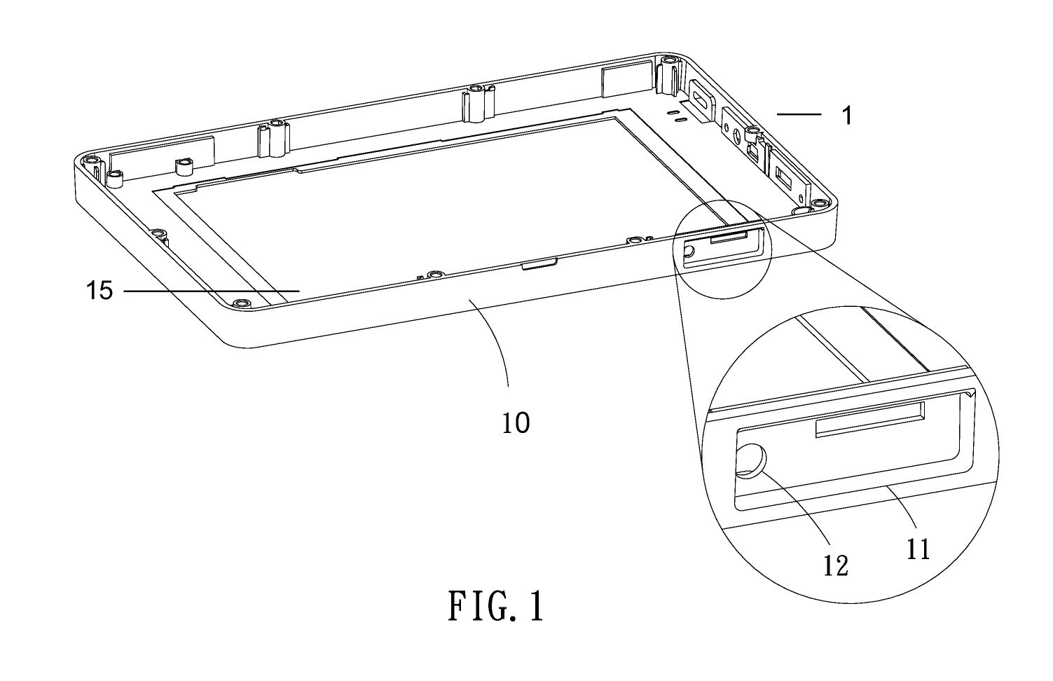

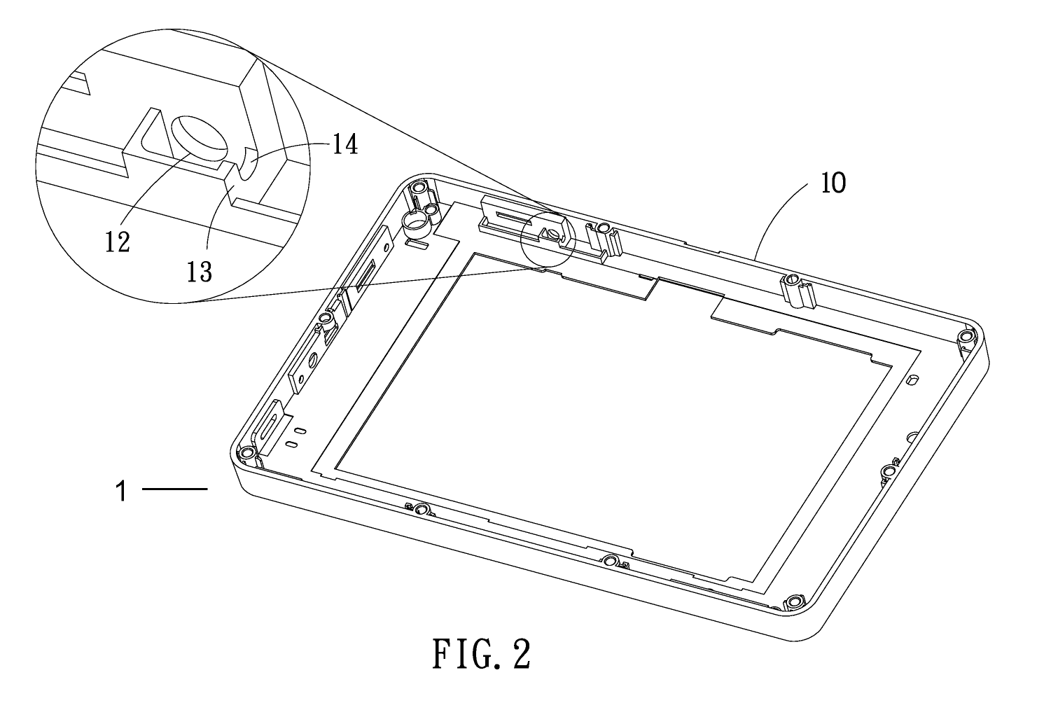

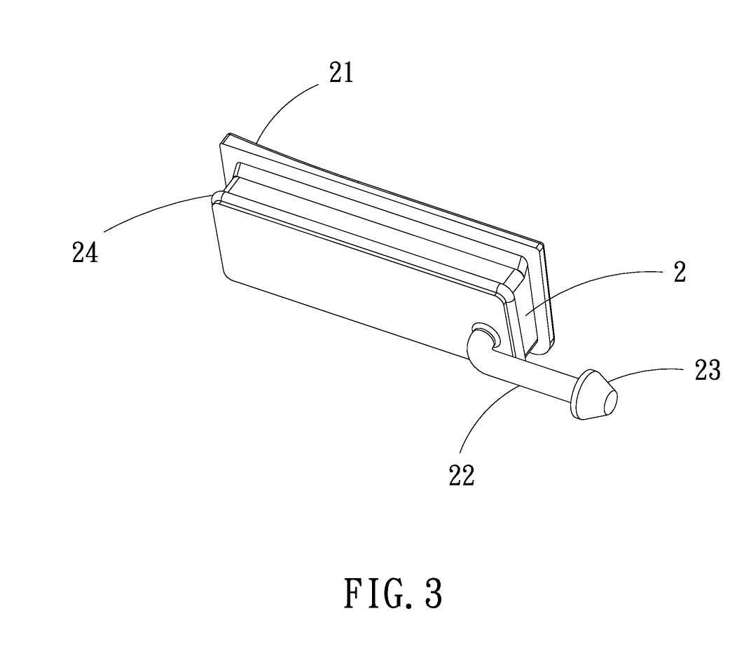

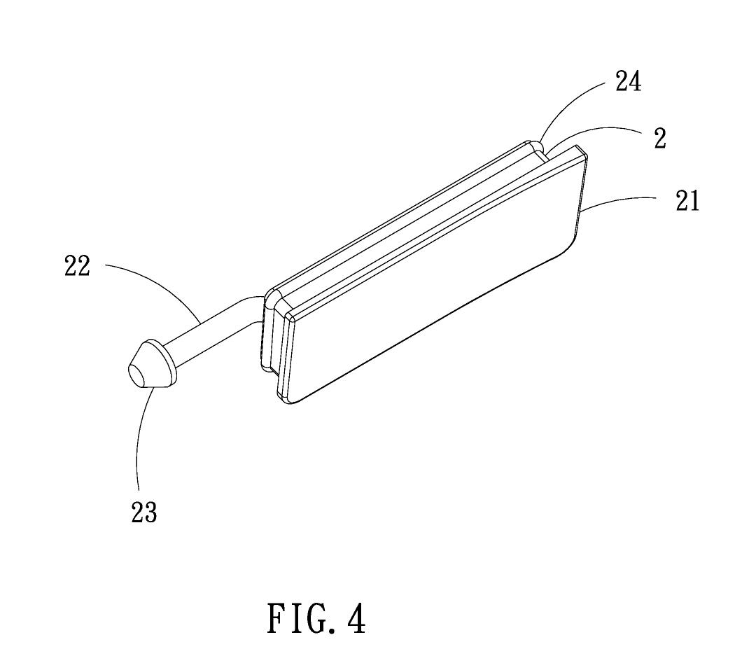

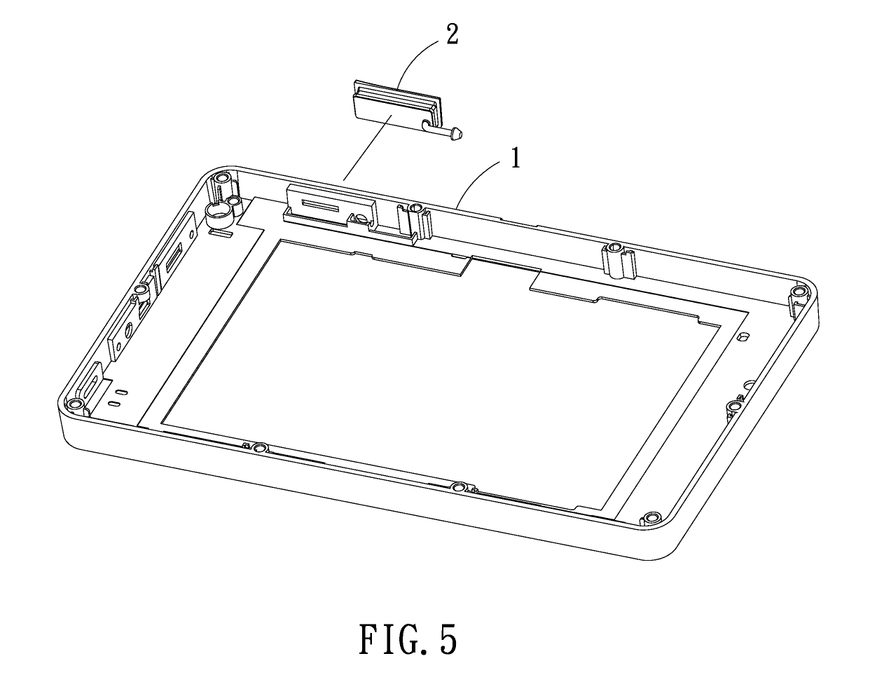

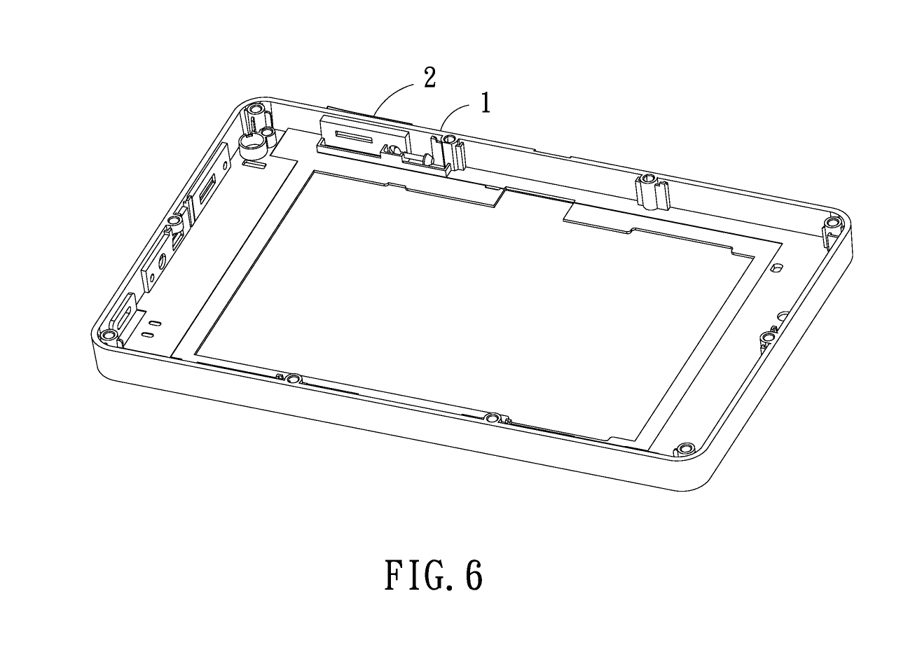

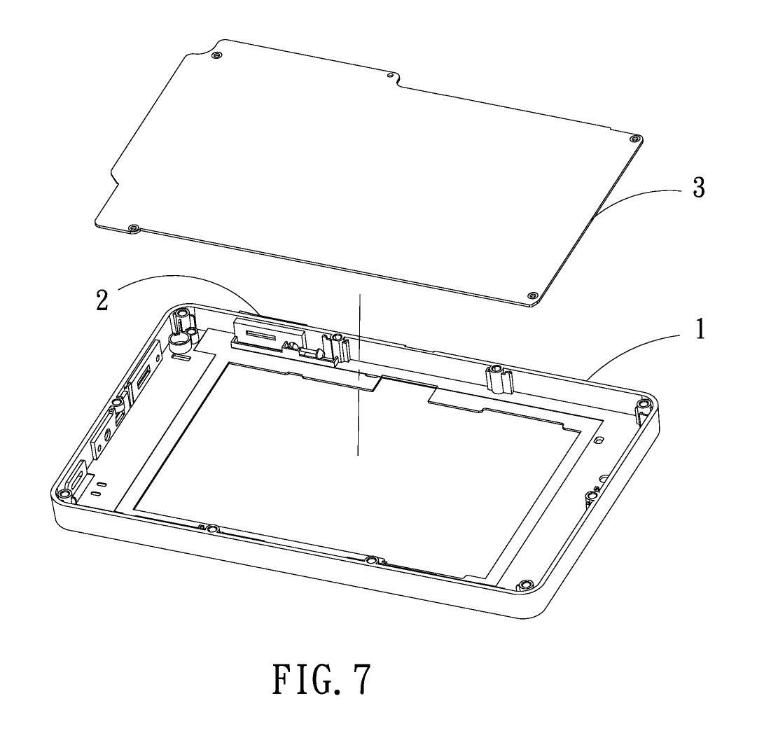

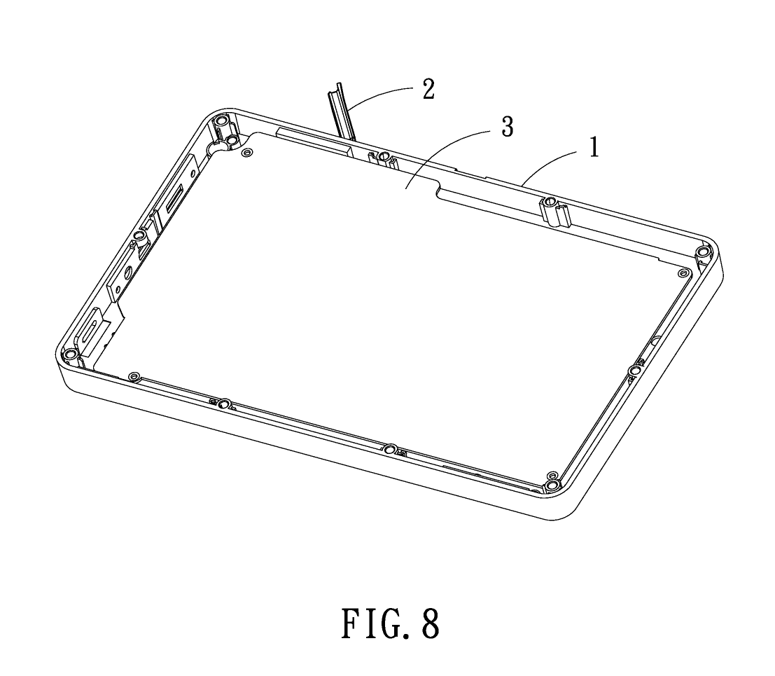

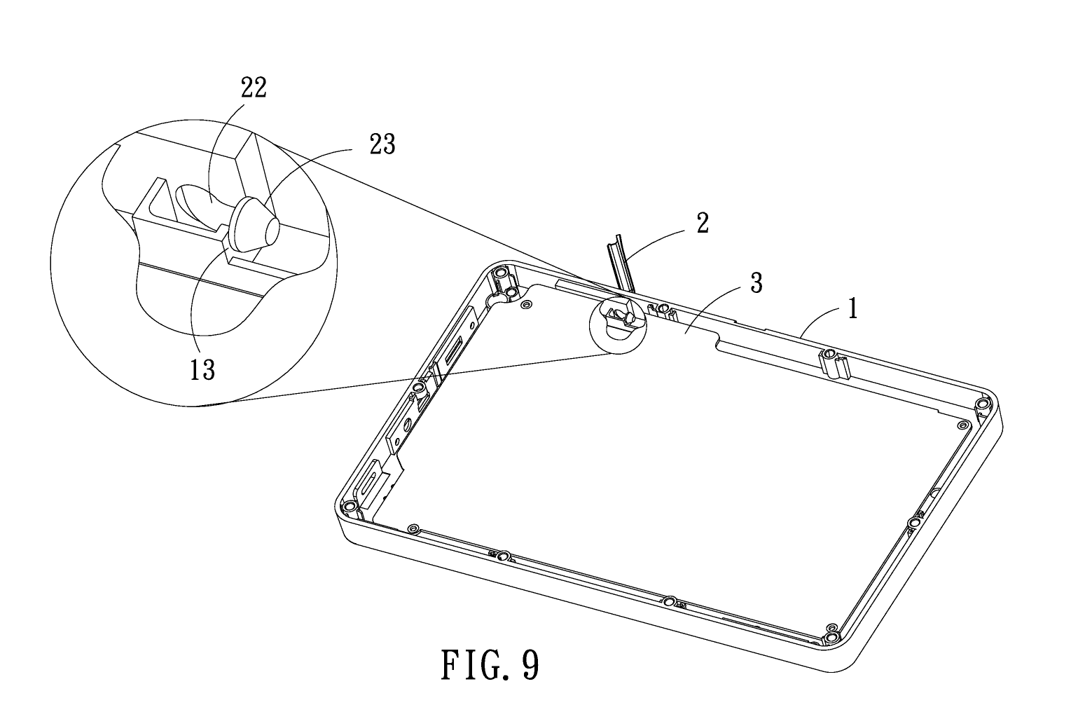

Referring to FIGS. 1 to 9, a waterproof structural assembly particularly for an electronic part in accordance with the invention comprises the following components as discussed in detail below.

A frame 1 is rectangular and comprises a large, substantially rectangular opening 15 through center, a loop flange 10 on top edges, a rectangular recess 11 on one side of the flange 10, a channel 12 through the recess 11 to communicate inside of the frame 1 with outside of the frame 1, a wall 13 facing and spaced from one end of the channel 12 within the frame 1, and a U-shaped groove 14 through the wall 13.

A sealing cap 2 is made of flexible material (e.g., plastic) and is complementary to the recess 11. The sealing cap 2 comprises an outer rectangular handle 21, an inner rectangular engaging member 24 spaced from the handle 21, an L-shaped peg 22 having a cross-section of circle formed on one surface of the engaging member 24, and a substantially truncated conic member 23 formed at one end of the peg 22.

The truncated conic member 23 is larger than a diameter of the peg 22. Width of the groove 14 is greater than the diameter of the peg 22 but less than a diameter of one end of the truncated conic member 23 joining the peg 22. The bore of the channel 12 is greater than the diameter of the peg 22 and greater than the diameter of one end of the truncated conic member 23 joining the peg 22. A periphery of the engaging member 14 is slightly greater than that of a bottom of the recess 11.

In assembly, both the truncated conic member 23 and the peg 22 pass the channel 12 by inserting and bending. After passing, the peg 22 rests upon the groove 14 and the truncated conic member 23 further passes the wall 13 to dispose externally of the wall 13 within the frame 1. Further, a sealing fastening of the engaging member 14 in the recess 11 can be carried out after inserting a substantial portion of the sealing cap 2 into the recess 11. In this position, the handle 21 is disposed externally of the recess 11.

An electronic part such as printed circuit board (PCB) 3 is fastened in the frame 1 to cover the opening 15. Next, a base (not shown) and a cover (not shown) can be secured to the frame 1 from bottom and top respectively to form a container to enclose the PCB 3 in a waterproof arrangement.

For disengaging the sealing cap 2 from the frame 1, an individual may pivot the handle 21 about the peg 22 and pull both the peg 22 and the truncated conic member 23 out of the channel 12 and the recess 11 sequentially.

While the invention has been described in terms of preferred embodiments, those skilled in the art will recognize that the invention can be practiced with modifications within the spirit and scope of the appended claims.

What is claimed is:

1. A structural assembly comprising:
a rectangular, hollow flame comprising a loop flange disposed along edges, a recess on one side of the flange, a channel through the recess to communicate with inside of the frame, a wall disposed within the frame, the wall facing and spaced from the channel, and a groove through the wall; and
a flexible sealing cap complimentary to the recess, the sealing cap comprising an outer handle, an inner engaging member spaced from the handle, an L-shaped peg formed on one surface of the engaging member distal the handle, and an enlargement formed at one end of the peg;
wherein the enlargement is larger than the peg;
wherein width of the groove is greater than the peg;
wherein the enlargement is larger than the width of the groove;
wherein both the peg and the enlargement are capable of passing the channel; and
wherein a periphery of the engaging member is greater than that of a bottom of the recess.
